(19) United States
(12) Patent Application Publication
(10) Pub. No.: US 2014/0048828 A1
(43) Pub. Date: Feb. 20, 2014

(54) LED DISPLAY PANEL AND LED DISPLAY APPARATUS

(71) Applicant: Macroblock Inc., Hsinchu (TW)

(72) Inventors: Li-Chang YANG, Hsinchu (TW); Chung-Yu WU, Hsinchu (TW); Hung-Ping LEE, Hsinchu (TW)

(73) Assignee: Macroblock Inc., Hsinchu (TW)

(21) Appl. No.: 13/967,974

(22) Filed: Aug. 15, 2013

(30) Foreign Application Priority Data
Aug. 17, 2012 (TW) 101129965

(51) Int. Cl. H01L 33/08

(52) U.S. Cl. CPC H01L 33/08
USPC 257/89

(57) ABSTRACT

An LED display panel includes: a semiconductor wafer having a top surface; a plurality of LED elements disposed over the top surface of the semiconductor wafer, each of the LED elements having an electrode contact; and a plurality of driving circuits formed in the semiconductor wafer. Each of the driving circuits has an electrode-connecting contact that is disposed on the top surface of the semiconductor wafer and that is bonded to the electrode contact of a respective one of the LED elements.

### CROSS-REFERENCE TO RELATED APPLICATION

This application claims priority of Taiwanese Application No. 101129965, filed on Aug. 17, 2012.

### BACKGROUND OF THE INVENTION

1. Field of the Invention

The invention relates to a light emitting diode (LED) display panel and an LED display apparatus including the same, more particularly to an LED display panel having a semiconductor wafer, LED elements and driving circuits formed in the semiconductor wafer.

2. Description of the Related Art

FIG. 1 illustrates a conventional LED display panel which comprises a printed circuit board (PCB) 11, a plurality of LED elements 12 that are surface-mounted to a top face of the PCB 11 through reflow soldering techniques and that are arranged in an array, and a plurality of chip-scale driving circuit devices 13 that are surface-mounted to a bottom face of the PCB 11 through reflow soldering techniques.

The PCB 11 includes an insulative substrate 111 and a plurality of transmitting line sets 112 that are formed in the insulative substrate 111 and that electrically connect the LED elements 12 to the driving circuit devices 13, respectively. Each of the LED elements 12 includes at least one LED chip 121 that is electrically connected to a respective one of the driving circuit devices 13 through a respective one of the transmitting line sets 112, and an LED enclosing member 122 that encloses the LED chip 121. Each of the LED elements 12 defines a pixel of the conventional LED display panel.

Each of the driving circuit devices 13 includes a semiconductor chip 131, a circuit enclosing member 132 which encloses the semiconductor chip 131, and two lead pins 133 that extend through the circuit enclosing member 132 and that are electrically connected to two adjacent ones of the transmitting line sets 112. The semiconductor chip 131 has a driving circuit (not shown) built in a semiconductor die (not shown) which is diced from an integrated circuit wafer.

The circuit states (ON/OFF) of the LED elements 12 are controlled by control signals output from the driving circuits devices 13.

The conventional LED display panel is disadvantageous in that a manufacturing problem arises when the resolution (i.e., dots per inch (dpi)) of the LED display panel is increased, i.e., when the density of the LED elements 12 and the density of the driving circuit devices 13 are increased. As such, the space among the pixels is considerably decreased and the dimensions of the lead pins 133 of the driving circuit devices 13 and the transmitting line sets 112 are required to be reduced correspondingly, which results in difficulties in aligning the lead pins 133 with the transmitting line sets 112 for subsequent reflow soldering of the lead pins 133 and the transmitting line sets 112 and in an increased possibility of generating defective pixels.

### SUMMARY OF THE INVENTION

Therefore, an object of the present invention is to provide an LED display panel that can overcome the aforesaid drawbacks associated with the prior art.

Another object of the present invention is to provide an LED display apparatus that includes the LED display panel.

According to one aspect of the present invention, there is provided an LED display panel that comprises: a semiconductor wafer having a top surface; a plurality of LED elements disposed over the top surface of the semiconductor wafer, each of the LED elements having an electrode contact; and a plurality of driving circuits formed in the semiconductor wafer. Each of the driving circuits has an electrode-connecting contact that is disposed on the top surface of the semiconductor wafer and that is bonded to the electrode contact of a respective one of the LED elements.

According to another aspect of the present invention, there is provided an LED display apparatus that comprises a housing having amounting side and an LED display panel. The LED display panel includes: a semiconductor wafer having a top surface, mounted in the housing, and in sealing contact with the mounting side of the housing; a plurality of LED elements disposed over the top surface of the semiconductor wafer, each of the LED elements having an electrode contact; and a plurality of driving circuits formed in the semiconductor wafer. Each of the driving circuits has an electrode-connecting contact that is disposed on the top surface of the semiconductor wafer and that is bonded to the electrode contact of a respective one of the LED elements.

### BRIEF DESCRIPTION OF THE DRAWINGS

In drawings which illustrate embodiments of the invention,

FIG. 1 is a schematic cross sectional view of a conventional LED display apparatus;

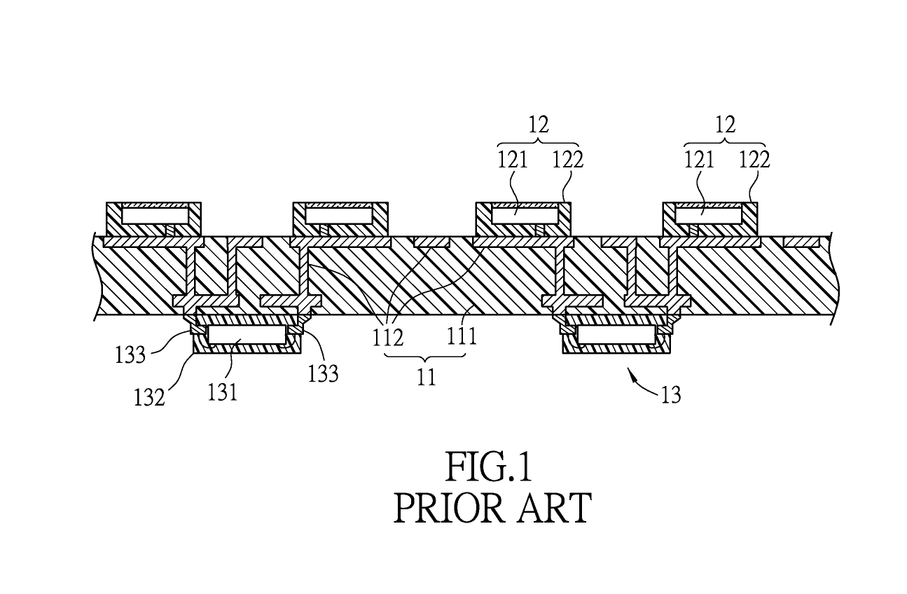

FIG. 2 is a fragmentary perspective view of the first preferred embodiment of an LED display panel according to the present invention;

FIG. 3 illustrates an array of series-connected driving circuits of the first preferred embodiment;

FIG. 4 illustrates an array of series-connected driving circuits of the second preferred embodiment of the LED display panel according to the pre sent invention;

FIG. 5 is a fragmentary schematic top view illustrating the third preferred embodiment of the LED display panel according to the present invention;

FIG. 6 is a partly sectional view illustrating LED elements of the fourth preferred embodiment of the LED display panel according to the present invention; and

FIG. 7 is a partly sectional view illustrating an LED display apparatus including the LED display panel of the second preferred embodiment.

### DETAILED DESCRIPTION OF THE PREFERRED EMBODIMENTS

Before the present invention is described in greater detail with reference to the accompanying preferred embodiments, it should be noted herein that like elements are denoted by the same reference numerals throughout the disclosure.

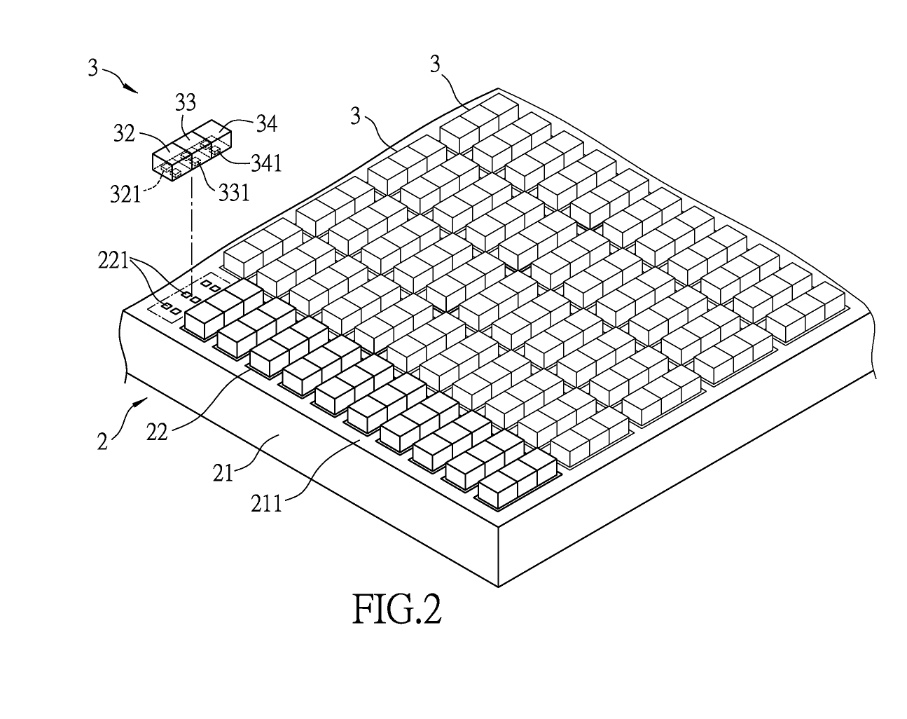

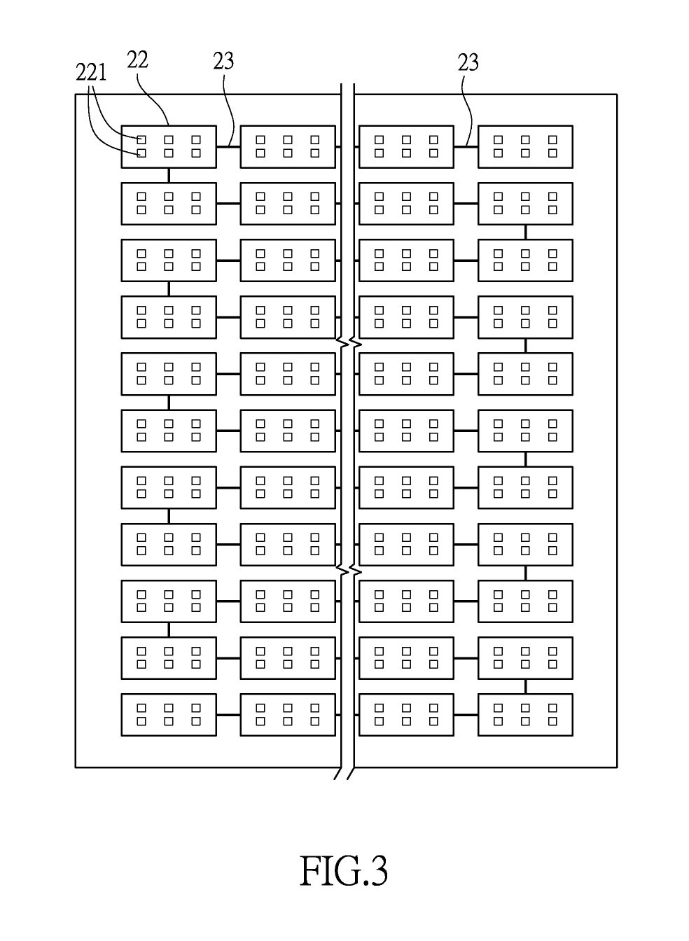

FIGS. 2 and 3 illustrate the first preferred embodiment of an LED display panel 2 according to the present invention. The LED display panel 2 can display an image based on an image signal input into the LED display panel 2. The LED display panel 2 includes a semiconductor wafer 21, a plurality of LED elements 3, a plurality of driving circuits 22, and a plurality of transmission line sets 23. Each of the LED elements 3 cooperates with a respective one of the driving circuits 22 to define a pixel of the LED display panel 2.

The semiconductor wafer 21 has a top surface 211 and is made from a material selected from the group consisting of silicon, germanium, silicon-germanium, and III-V semiconductor materials. The material for the semiconductor wafer 21 is selected based on the functions to be performed by the driving circuits 22.

The LED elements 3 are disposed over the top surface 211 of the semiconductor wafer 21, and are arranged in an array. Each of the LED elements 3 includes a red LED chip 32 that has a pair of electrode contacts 321 (serving as anode and cathode contacts, respectively) and that emits a red light when activated, a green LED chip 33 that has a pair of electrode contacts 331 and that emits a green light when activated, and a blue LED chip 34 that has a pair of electrode contacts 341 and that emits a blue light when activated.

It is noted that each of the LED elements 3 may include only one LED chip or more than three LED chips with various colors based on the actual requirements. For example, each of the LED elements 3 may further include another blue LED chip, or a violet LED chip.

In this embodiment, the LED chips 32, 33, and 34 of each of the LED elements 3 are disposed along a straight line. Alternatively, the LED chips 32, 33, and 34 of each of the LED elements 3 may be disposed in a triangular or other shaped relationship. The LED chips 32, 33, and 34 of the LED elements 3 may be electrically connected in series, in parallel or in series-parallel.

The driving circuits 22 are formed in the semiconductor wafer 21, and are arranged in an array corresponding to that of the LED elements 3. Each of the driving circuits 22 includes three pairs of electrode-connecting contacts 221. The electrode-connecting contacts 221 of each driving circuit 22 are disposed on the top surface 211 of the semiconductor wafer 21, and are bonded to the electrode contacts 321, 331, 341 of a respective one of the LED elements 3, respectively.

In this embodiment, each of the driving circuits 22 (except for the first or an endmost one of the driving circuits 22 which receives a control input from an external source) receives a control input including series data (SDI) and clock (CKI) from a previous driving circuit 22, and performs calculation upon the control input to generate a calculated control input that includes a calculated series data (SDO) and clock (CKO) and that is to be transmitted to the next driving circuit 22, so that operation of each of the LED elements 3 can be controlled according to the control input of the corresponding driving circuit 22. An equivalent circuit of each of the driving circuits 22 includes, for example, an IC MBI6020GP, modulated resistor, capacitor, and Zener diode. The IC MBI6020GP mainly includes a shift register, a control unit, a comparator, and a counter.

The transmission line sets 23 are formed in the semiconductor wafer 21, and are connected to the driving circuits 22 so as to permit transmission of the control input to the driving circuits 22. In this embodiment, the driving circuits 22 are electrically connected in series with one another through the transmission line sets 23. Alternatively, each row or each column of the driving circuits 22 may be electrically connected in parallel through the transmission line sets 23.

The driving circuits 22 and the transmission line sets 23 are both formed in the semiconductor wafer 21 through semiconductor processing techniques that include lithography processes, etching processes, thin film deposition processes and diffusion processes.

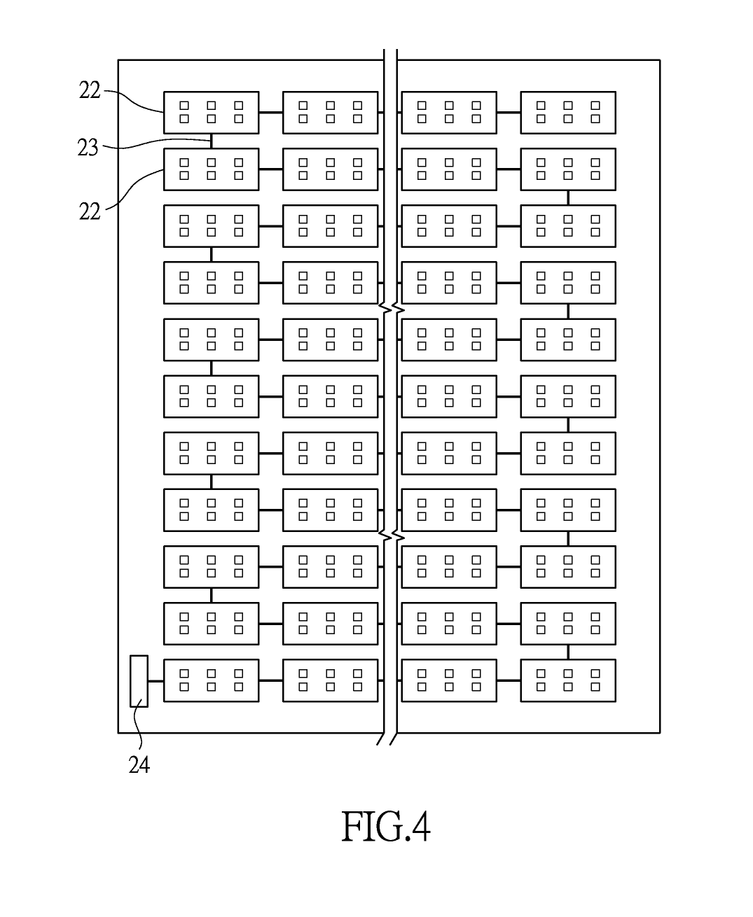

FIG. 4 illustrates the second preferred embodiment of the LED display panel 2 according to the present invention. The second preferred embodiment differs from the previous embodiment in that the LED display panel 2 further includes an input circuit 24 which is formed in the semiconductor wafer 21. The input circuit 24 is connected to an endmost one of a first row of the array of the driving circuits 22, and is configured to generate and send the control input to the endmost one of the first row of the array of the driving circuits 22. The transmission line sets 23 are disposed between and interconnect two adjacent ones of the driving circuits 22 such that the driving circuits 22 are electrically connected in series with one another through the transmission line sets 23.

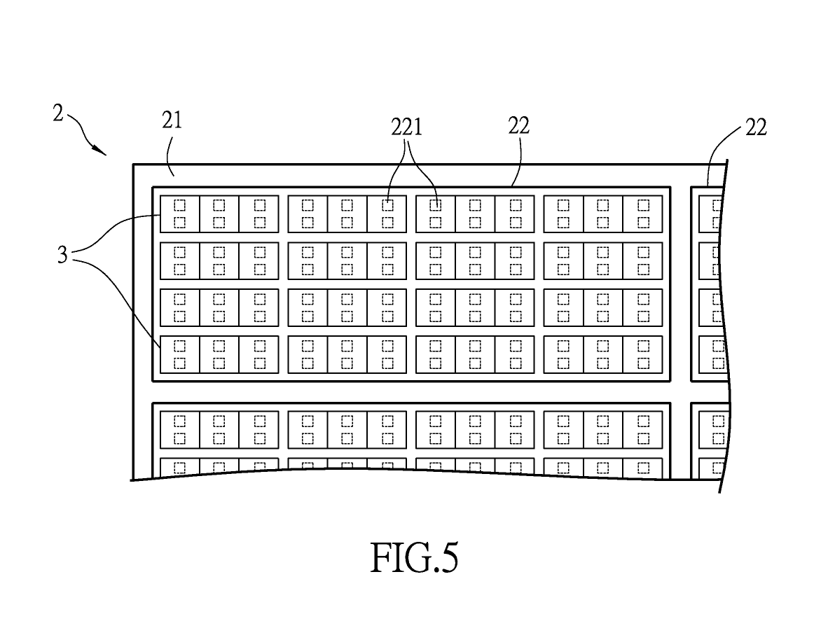

FIG. 5 illustrates the third preferred embodiment of the LED display panel 2 according to the present invention. The third preferred embodiment differs from the first preferred embodiment in that each of the driving circuits 22 of the LED display panel 2 is connected to and controls operation of a plurality of the LED elements 3, and includes a plurality of the electrode-connecting contacts 221 that are bonded to the electrode contacts 321, 331, 341 of respective ones of the LED elements 3, respectively.

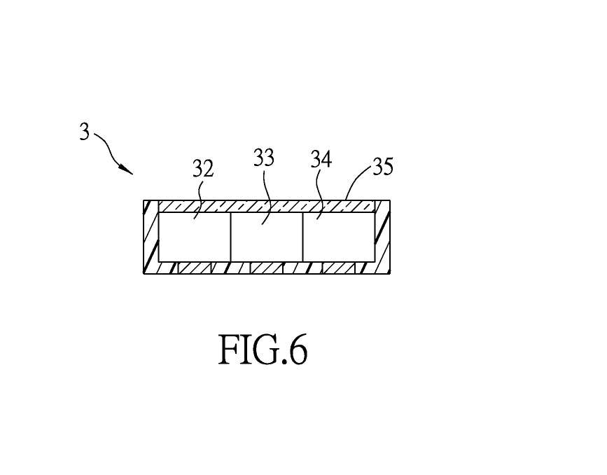

FIG. 6 illustrates the fourth preferred embodiment of the LED display panel 2 according to the present invention. The fourth preferred embodiment differs from the previous embodiments in that this embodiment further includes an enclosing member 35 enclosing the red LED chip 32, the green LED chip 33, and the blue LED chip 34 of the corresponding LED element 3. A top portion of the enclosing member 35 is transparent so that light emitted from the LED chips 32, 33, 34 can pass therethrough.

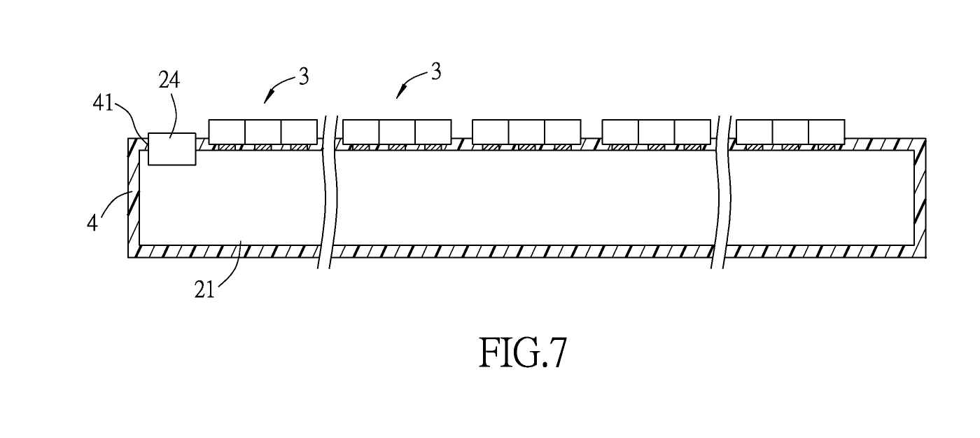

FIG. 7 illustrates an LED display apparatus that includes a housing 4 and an LED display panel 2 having a structure the same as that of the second preferred embodiment. The housing 4 has a mounting side 41. The semiconductor wafer 21 of the LED display panel 2 is mounted in the housing 4, and is in sealing contact with the mounting side 41 of the housing 4 so that the semiconductor wafer 21 can be protected from environmental aging.

Since the driving circuits 22 and the transmission line sets 23 are both formed in the same semiconductor wafer 21, the aforesaid alignment problem arising from the increase of the resolution (i.e., dpi) of the conventional LED display panel can be eliminated. In addition, since the LED elements 3 can be directly mounted on the semiconductor wafer 21, the PCB employed in the conventional LED display panel can be dispensed with and the overall profile of the LED display panel of the present invention can be considerably reduced as compared to that of the conventional LED display panel.

While the present invention has been described in connection with what are considered the most practical and preferred embodiments, it is understood that this invention is not limited to the disclosed embodiments but is intended to cover various arrangements included within the spirit and scope of the broadest interpretation so as to encompass all such modifications and equivalent arrangements.

What is claimed is:

1. An LED display panel comprising:
a semiconductor wafer having a top surface;
a plurality of LED elements disposed over said top surface of said semiconductor wafer, each of said LED elements having an electrode contact; and
a plurality of driving circuits formed in said semiconductor wafer, each of said driving circuits having an electrode-connecting contact that is disposed on said top surface of said semiconductor wafer and that is bonded to said electrode contact of a respective one of said LED elements.

2. The LED display panel of claim 1, wherein said LED elements are arranged in an array, said driving circuits being arranged in an array, each of said LED elements cooperating with the respective one of said driving circuits to define a pixel of said LED display panel.

3. The LED display panel of claim 2, further comprising a plurality of transmission line sets that are formed in said semiconductor wafer, said transmission line sets being connected to said driving circuits and permitting transmission of a control input to said driving circuits through said transmission line sets.

4. The LED display panel of claim 3, further comprising an input circuit that is formed in said semiconductor wafer and that is connected to an endmost one of a first row of the array of said driving circuits, said input circuit being configured to generate and send said control input to said endmost one of the first row of the array of said driving circuits, each of said transmission line sets being disposed between and interconnecting two adjacent ones of said driving circuits such that said driving circuits are electrically connected in series with one another through said transmission line sets.

5. The LED display panel of claim 1, wherein each of said LED elements includes a red LED chip, a green LED chip, and a blue LED chip.

6. The LED display panel of claim 5, wherein each of said LED elements further includes an enclosing member that encloses said red LED chip, said green LED chip and said blue LED chip.

7. An LED display apparatus comprising:
a housing having a mounting side; and
an LED display panel including:
a semiconductor wafer having a top surface, mounted in said housing, and in sealing contact with said mounting side of said housing,
a plurality of LED elements disposed over said top surface of said semiconductor wafer, each of said LED elements having an electrode contact, and
a plurality of driving circuits formed in said semiconductor wafer, each of said driving circuits having an electrode-connecting contact that is disposed on said top surface of said semiconductor wafer and that is bonded to said electrode contact of a respective one of said LED elements.

8. The LED display apparatus of claim 7, wherein said LED elements of said LED display panel are arranged in an array, said driving circuits of said LED display panel being arranged in an array, each of said LED elements cooperating with the respective one of said driving circuits to define a pixel of said LED display panel.

9. The LED display apparatus of claim 8, wherein said LED display panel further includes a plurality of transmission line sets that are formed in said semiconductor wafer, said transmission line sets being connected to said driving circuits and permitting transmission of a control input to said driving circuits through said transmission line sets.

10. The LED display apparatus of claim 9, wherein said LED display panel further includes an input circuit that is formed in said semiconductor wafer and that is connected to an endmost one of a first row of the array of said driving circuits, said input circuit being configured to generate and send said control input to said endmost one of the first row of the array of said driving circuits, each of said power transmission line sets being disposed between and interconnecting two adjacent ones of said driving circuits such that said driving circuits are electrically connected in series with one another through said transmission line sets.

11. The LED display apparatus of claim 10, wherein each of said LED elements of said LED display panel includes a red LED chip, a green LED chip, and a blue LED chip.

12. The LED display apparatus of claim 11, wherein each of said LED elements of said LED display panel further includes an enclosing member that encloses said red LED chip, said green LED chip and said blue LED chip.
